(19) United States
(12) Patent Application Publication
(10) Pub. No.: US 2025/0380530 A1
(43) Pub. Date: Dec. 11, 2025

(54) IMAGE SENSOR

(71) Applicant: Samsung Electronics Co., Ltd., Suwon-si (KR)

(72) Inventors: Wonhyeok KIM, Suwon-si (KR); Uisik Kim, Suwon-si (KR); Heegeun Jeong, Suwon-si (KR); Ingyu Hyun, Suwon-si (KR)

(73) Assignee: Samsung Electronics Co., Ltd., Suwon-si (KR)

(21) Appl. No.: 18/966,573

(22) Filed: Dec. 3, 2024

(30) Foreign Application Priority Data
Jun. 5, 2024 (KR) 10-2024-0073530

(51) Int. Cl. H01L 27/146

(52) U.S. Cl. CPC H10F 39/813; H10F 39/182; H10F 39/8053; H10F 39/807; H10F 39/809

(57) ABSTRACT

Disclosed embodiments include an image sensor having a first layer including a first substrate and first to fourth pixel regions arranged in a 2×2 shape in first and second directions, each of the first to fourth pixel regions including a photodiode, an active region, and a transfer gate, and a stacked second layer including a second substrate and a plurality of transistors connected to the active regions, wherein the first to fourth pixel regions share a floating diffusion region which is connected to the active regions in a diagonal direction parallel to the upper surface of the first substrate, wherein in each of the first to fourth pixel regions, the transfer gate includes a first gate region adjacent to the active region in the first and second directions, and a second gate region above the first gate region.

### CROSS-REFERENCE TO RELATED APPLICATION(S)

This application claims benefit of priority to Korean Patent Application No. 10-2024-0073530, filed on Jun. 5, 2024, in the Korean Intellectual Property Office, the disclosure of which is incorporated herein by reference in its entirety.

### TECHNICAL FIELD

The present disclosure relates to an image sensor.

### BACKGROUND

An image sensor is a semiconductor-based sensor receiving light and generating an electrical signal, and may include a pixel array having a plurality of pixels, a logic circuit driving the pixel array and generating an image, and the like. Each of the pixels may include a photodiode, and a pixel circuit converting charges generated by the photodiode into an electrical signal. As the number of the pixels included in the image sensor increases and a size of each of the pixels decreases, various methods for effectively forming transistors disposed in each of the pixels to provide the pixel circuit have been proposed.

### SUMMARY

Some embodiments consistent with the present disclosure provide an image sensor changing a shape of a transfer gate disposed between a photodiode and a floating diffusion region to effectively form a movement path for charges generated in the photodiode and then accumulated in the floating diffusion region.

According to some embodiments consistent with the present disclosure, an image sensor includes a first layer including a first substrate and first to fourth pixel regions arranged in a 2×2 shape in first and second directions, parallel to an upper surface of the first substrate and intersecting each other, each of the first to fourth pixel regions including a photodiode, an active region formed in the first substrate, and a transfer gate; and a second layer stacked with the first layer, and including a second substrate and a plurality of transistors connected to the active region of each of the plurality of pixel regions, wherein the first to fourth pixel regions share a floating diffusion region located in a central portion of a group region including the first to fourth pixel regions, the floating diffusion region is connected to the active region of each of the first to fourth pixel regions in a diagonal direction, intersecting the first and second directions and parallel to the upper surface of the first substrate, and in each of the first to fourth pixel regions, the transfer gate includes a first gate region disposed in the first substrate and adjacent to the active region in the first and second directions, and a second gate region disposed above the first gate region.

According to some embodiments consistent with the present disclosure, an image sensor includes a plurality of pixel regions arranged in a first direction and a second direction, parallel to an upper surface of a substrate and intersecting each other; and a pixel isolation layer extending in the first and second directions between the plurality of pixel regions, wherein each of the plurality of pixel regions includes at least one photodiode disposed in the substrate; at least one active region disposed above the photodiode in a third direction, perpendicular to the upper surface of the substrate; a first gate region disposed around the active region in the first and second directions and buried in the substrate; and a second gate region disposed above a portion of the upper surface of the first gate region.

According to some embodiments consistent with the present disclosure, an image sensor includes a substrate; an external pixel isolation layer disposed in the substrate and extending along a boundary of a pixel group including a plurality of pixel regions arranged in a first direction and a second direction, parallel to the upper surface of the substrate; internal pixel isolation layers disposed in a region in the boundary and dividing the plurality of pixel regions; a plurality of photodiodes disposed in the plurality of pixel regions; a plurality of active regions disposed on the plurality of photodiodes; a floating diffusion region disposed between the internal pixel isolation layers in the first and second directions, and connected to the plurality of active regions in a first diagonal direction and a second diagonal direction, intersecting the first and second directions and parallel to the upper surface of the substrate; and a plurality of transfer gates disposed in the plurality of pixel regions, wherein, in each of the plurality of pixel regions, the active region is disposed between the transfer gates in the first direction, and between the transfer gates in the first diagonal direction or the second diagonal direction.

### BRIEF DESCRIPTION OF DRAWINGS

The above and other aspects, features, and embodiments consistent with the present disclosure will be more clearly understood from the following detailed description, taken in conjunction with the accompanying drawings, in which:

FIG. 1 is a block diagram schematically illustrating an image sensor according to some embodiments consistent with the present disclosure.

FIG. 2 is a view schematically illustrating a stacked structure of an image sensor according to some embodiments consistent with the present disclosure.

FIG. 3 is a view schematically illustrating a pixel circuit included in an image sensor according to some embodiments consistent with the present disclosure.

FIG. 4 is a view schematically illustrating a pixel array included in an image sensor according to some embodiments consistent with the present disclosure.

FIG. 5 is a view schematically illustrating a partial region of a first layer included in an image sensor according to some embodiments consistent with the present disclosure.

FIG. 6 is a view schematically illustrating a partial region of a second layer included in an image sensor according to some embodiments consistent with the present disclosure.

FIG. 7 is a cross-sectional view illustrating a cross-section of FIG. 5, taken along line I-I′.

FIG. 8 is an enlarged view of a partial region of FIG. 7.

FIG. 9 is a view schematically illustrating a structure of an image sensor according to some embodiments consistent with the present disclosure.

FIG. 10 is a view schematically illustrating a pixel circuit included in an image sensor according to some embodiments consistent with the present disclosure.

FIG. 11 is a view schematically illustrating a pixel array included in an image sensor according to some embodiments consistent with the present disclosure.

FIGS. 12 and 13 are views schematically illustrating a partial region of a first layer and a partial region of a second layer included in an image sensor according to some embodiments consistent with the present disclosure.

FIG. 14 is a view schematically illustrating a structure of an image sensor according to some embodiments consistent with the present disclosure.

FIG. 15 is a view schematically illustrating a pixel array included in an image sensor according to some embodiments consistent with the present disclosure.

FIGS. 16 and 17 are views schematically illustrating a partial region of a first layer included in an image sensor according to some embodiments consistent with the present disclosure.

FIG. 18 is a view schematically illustrating a partial region of a second layer included in an image sensor according to some embodiments consistent with the present disclosure.

FIG. 19 is a cross-sectional view illustrating a cross-section of FIG. 16, taken along line II-II′.

FIGS. 20 and 21 are views schematically illustrating a structure of an image sensor according to some embodiments consistent with the present disclosure.

### DETAILED DESCRIPTION

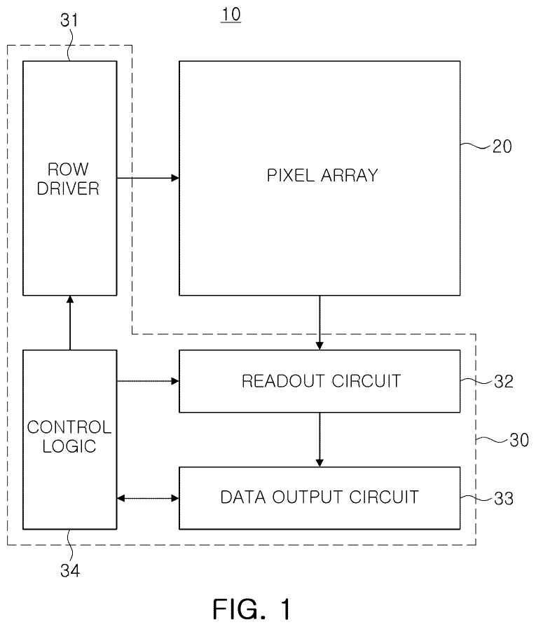

Hereinafter, embodiments will be described with reference to the attached drawings. FIG. 1 is a block diagram schematically illustrating an image sensor according to some embodiments consistent with the present disclosure.

Referring to FIG. 1, an image sensor 10 may include a pixel array 20, a logic circuit 30, and other elements.

Pixel array 20 may include a plurality of pixels arranged in an array form along a plurality of rows and a plurality of columns. Each of the plurality of pixels may include at least one photoelectric conversion element generating charges in response to light, a pixel circuit generating a voltage signal corresponding to the charges generated by the photoelectric conversion element, and the like. The photoelectric conversion element may include a photodiode comprising a semiconductor material, and/or an organic photodiode comprising an organic material, or the like.

For example, a pixel array may include a floating diffusion region, a transfer transistor, a reset transistor, a drive transistor, a select transistor, and the like. A configuration of pixels of a pixel array may be changed depending on embodiments. As an example, each of the pixels may include a larger number of transistors to support additional functionality. Additionally, the pixels may be implemented as digital pixels, in which case each (or at least one) of the pixels may include an analog-to-digital converter outputting a digital pixel signal.

With further reference to FIG. 1, logic circuit 30 may include circuits controlling pixel array 20. For example, logic circuit 30 may include a row driver 31, a readout circuit 32, a data output circuit 33, a control logic 34, and the like. Row driver 31 may drive pixel array 20 in units of row lines. For example, row driver 31 may generate a transfer control signal controlling the transfer transistor of pixel array 20, a reset control signal controlling the reset transistor, a select control signal controlling the select transistor, or the like, to input the same in a given row line of pixel array 20.

As an example, among the pixels of pixel array 20, pixels arranged at the same position in a row direction (e.g., horizontal direction in FIG. 1) may share the same column line. For example, pixels arranged at the same position in a column direction (e.g., vertical direction in FIG. 1) may be simultaneously selected by row driver 31, and a pixel signal may be output through column lines. In some embodiments, readout circuit 32 may simultaneously receive voltage signals from pixels selected by row driver 31 through the column lines. For example, readout circuit 32 may sequentially receive a reset voltage and a pixel voltage from each of the pixels, and the pixel voltage may be a voltage in which charges generated in a photodiode of each of the pixels are reflected in the reset voltage.

Readout circuit 32 may include a plurality of correlated double samplers and a plurality of counters, and the correlated double samplers may be connected to the pixels through the column lines. The correlated double samplers may read a voltage signal through the column lines, from the pixels connected to a row line selected by a row line select signal of row driver 31. In some embodiments, among the input terminals of each of the correlated double samplers, an input terminal may be connected to the column lines, and a different input terminal may receive a ramp voltage.

According to some embodiments, an output terminal of each of the correlated double samplers may be connected to the counters, and the counters may count a time that the output of each of the correlated double samplers may be maintained at a specific voltage, to generate a digital pixel signal. For example, the counter may count a time when a ramp voltage input to the correlated double sampler is greater than a voltage of the column line, to convert output of the correlated double sampler into a digital pixel signal. Data output circuit 33 may, e.g., include a memory such as a latch temporarily storing a digital pixel signal, a buffer circuit, or the like.

Control logic 34 may include a timing controller controlling an operation timing of row driver 31, readout circuit 32, and data output circuit 33. In some embodiments, control logic 34 may determine a format of data to be output by data output circuit 33 or may perform preprocessing of data to be output by data output circuit 33.

When reading the reset voltage and the pixel voltage from each of the pixels, row driver 31 may turn on the transfer transistor included in each of the pixels at least once. When the transfer transistor is turned on, charges accumulated in the photodiode may move to the floating diffusion region. Since a level of the pixel voltage output from the pixel to the column line may be determined by the charges accumulated in the photodiode, it may be beneficial, according to some embodiments, to improve a movement efficiency of the charges moving from the photodiode to the floating diffusion region which improves the performance of image sensor 10.

In some embodiments, a floating diffusion region and/or an active region connected to the floating diffusion region may be disposed in a region having the highest charge density in the photodiode, and a transfer gate, which may be a gate of the transfer transistor, may be disposed around the active region. The transfer gate may include a buried region buried in a substrate on which the photodiode is formed, and the buried region may have a shape surrounding the floating diffusion region and/or the active region, which is connected to the floating diffusion region, in as wide a range as possible. Therefore, charges of the photodiode may move to the floating diffusion region with minimal loss by a turn-on voltage input to the transfer gate, and the quality of an image generated by image sensor 10 may be improved.

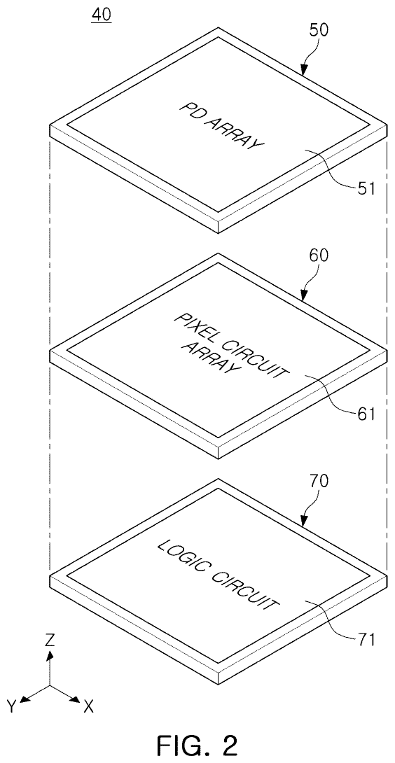

FIG. 2 is a view schematically illustrating a stacked structure of an image sensor according to some embodiments consistent with the present disclosure.

Referring to FIG. 2, an image sensor 40 may include a first layer 50, a second layer 60, and a third layer 70, stacked in order. First layer 50 may comprise a photodiode (PD) array 51 in which a plurality of photodiodes are arranged, and second layer 60 may comprise a pixel circuit array 61 including elements which are connected to the PD array 51 having arranged pixels. Third layer 70 may comprise a logic circuit 71 driving a plurality of pixels implemented by PD array 51 and pixel circuit array 61.

PD array 51 may include a plurality of pixel regions defined on, e.g., a first substrate of first layer 50, and each of the plurality of pixel regions may comprise at least one photodiode, a floating diffusion region in which charges of the photodiode are stored, a transfer gate, and the like. Pixel circuit array 61 may comprise a plurality of transistors formed on, e.g., a second substrate of second layer 60. Pixel circuit array 61 may include a reset transistor, a drive transistor, a select transistor, or the like, each of which or all of which may be connected to the floating diffusion region included in PD array 51. Logic circuit 71 may include a row driver, a readout circuit, a data output circuit, or the like.

In the example embodiment illustrated in FIG. 2, a photodiode and a plurality of transistors comprising one or more pixels may be disposed on first layer 50 and second layer 60. Therefore, a shape of the floating diffusion region and a shape of the transfer gate may be formed relatively freely in each of the plurality of pixel regions comprising PD array 51.

In some embodiments, a photodiode may be formed in the first substrate of first layer 50, and a floating diffusion region may be formed on a region of the photodiode having the highest charge density. In some embodiments, a transfer gate implementing a transfer transistor may have a shape that completely surrounds the floating diffusion region. Therefore, when a turn-on voltage is applied to the transfer gate, charges of the photodiode may move to the floating diffusion region with minimal loss.

Additionally, in some embodiments, an active region connected to the floating diffusion region may be formed on the region of the photodiode with the highest charge density. The transfer gate may be disposed around the active region, and may have a shape that completely surrounds the active region or a shape that surrounds as large a region as possible of the active region. When a turn-on voltage is applied to the transfer gate, charges of the photodiode may move through the active region to the floating diffusion region.

In some embodiments, the transfer gate formed on the first substrate of first layer 50 may include a first gate region buried in the first substrate. The first gate region may, e.g., be adjacent to the photodiode in the first substrate in a direction perpendicular to an upper surface of the first substrate, and may, e.g., further be adjacent to a floating diffusion region, and/or an active region connected to the floating diffusion region in the first substrate, in a direction parallel to the upper surface of the first substrate. As a result, a field may be formed by the voltage applied to the first gate region, and charges generated in the photodiode may move to the floating diffusion region with minimal loss along an efficient path.

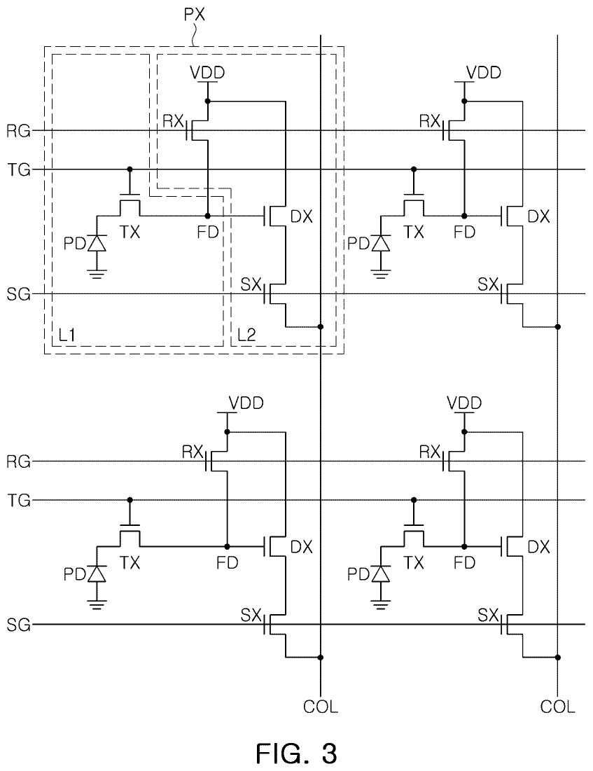

FIG. 3 is a view schematically illustrating a pixel circuit included in an image sensor, according to some embodiments consistent with the present disclosure.

Referring to FIG. 3, pixels PX according to some embodiments may include a photodiode PD, a transfer transistor TX, a reset transistor RX, a drive transistor DX, a select transistor SX, and the like, respectively. Transfer transistor TX may be connected between photodiode PD and a floating diffusion region FD. A gate of drive transistor DX may be connected to floating diffusion region FD, and may operate as a source-follower amplifier. Select transistor SX may be connected between drive transistor DX and a column line COL, and reset transistor RX may be connected between a power node supplying a power supply voltage VDD and floating diffusion region FD.

In some embodiments, a gate of transfer transistor TX may receive a transfer control signal TG, a gate of reset transistor RX may receive a reset control signal RG, and a gate of select transistor SX may receive a select control signal SG. As illustrated in the example of FIG. 3, pixels PX arranged in a row direction (e.g., horizontal direction in FIG. 3) may commonly receive transfer control signal TG, reset control signal RG, and select control signal SG. Pixels PX arranged in a column direction (e.g., vertical direction in FIG. 3) may share one of column lines COL.

With further reference to FIG. 3, in some embodiments, a portion of components included in each of pixels PX may be distributed and disposed in first and second layers L1 and L2, and first and second layers L1 and L2 may be stacked on each other. In FIG. 3, each of pixels PX, photodiode PD, transfer transistor TX, and floating diffusion region FD may be disposed on first layer L1, and each of reset transistor RX, drive transistor DX, and select transistor SX may be disposed on second layer L2. In some embodiments, a contact structure and a via structure may be connected to floating diffusion region FD, and reset transistor RX and drive transistor DX may be connected to the via structure.

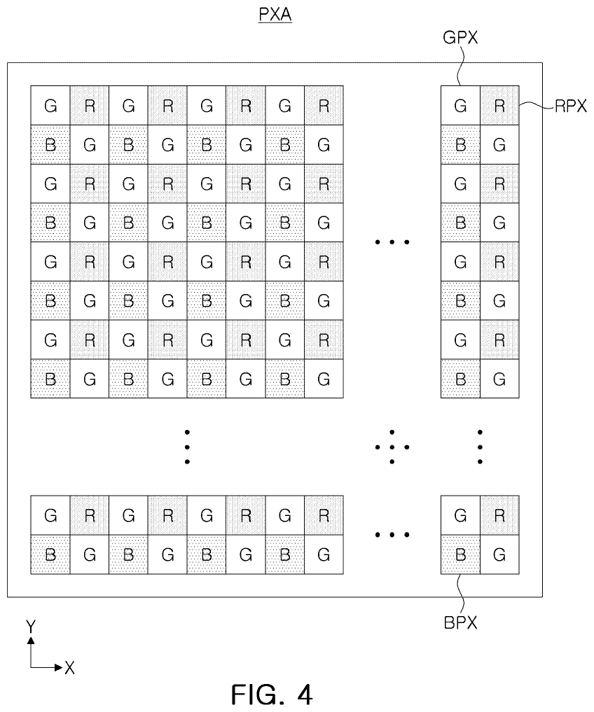

FIG. 4 is a view schematically illustrating a pixel array included in an image sensor, according to some embodiments consistent with the present disclosure.

Referring to FIG. 4, a pixel array PXA included in an image sensor, according to some embodiments, may include a plurality of pixels arranged in a first direction (e.g., X-axis direction) and a second direction (e.g., Y-axis direction). The plurality of pixels may be divided into red pixels RPX, green pixels GPX, and blue pixels BPX, depending, e.g., on a type of color filter included in each of the pixels. In some embodiments, the plurality of pixels may include a white pixel not filtering light in a specific wavelength band, or the like.

In pixel array PXA, according to some embodiments as illustrated in FIG. 4, each of the plurality of pixels may include at least one photodiode and transistors generating a voltage signal corresponding to a charge of the photodiode(s). For example, a pixel circuit of each of the plurality of pixels may have the structure described above with reference to FIG. 3.

With further reference to FIG. 4, and according some embodiments, pixel array PXA may include a first layer and a second layer, e.g., stacked on each other, and components of each of the plurality of pixels may be distributed and arranged on the first layer and the second layer. For example, in each of the plurality of pixels, a photodiode, a transfer transistor, and a floating diffusion region may be disposed in the first layer, and a reset transistor, a drive transistor, and a select transistor may be disposed in the second layer.

Therefore, degrees of design freedom of the transfer transistor and the floating diffusion region disposed on the first layer, along with the photodiode, may be expanded. In some embodiments, the photodiode may be formed on a first substrate of the first layer, and the floating diffusion region may be formed on a region of the photodiode in which a charge density is expected to be highest. Additionally, a transfer gate, which may be a gate of a transfer transistor, may be formed in a shape surrounding the floating diffusion region. Therefore, in a state in which a turn-on voltage for turning on the transfer transistor is applied to the transfer gate, movement efficiency of charges from the photodiode to the floating diffusion region may increase, and noise characteristics, or the like, of the image sensor may be improved.

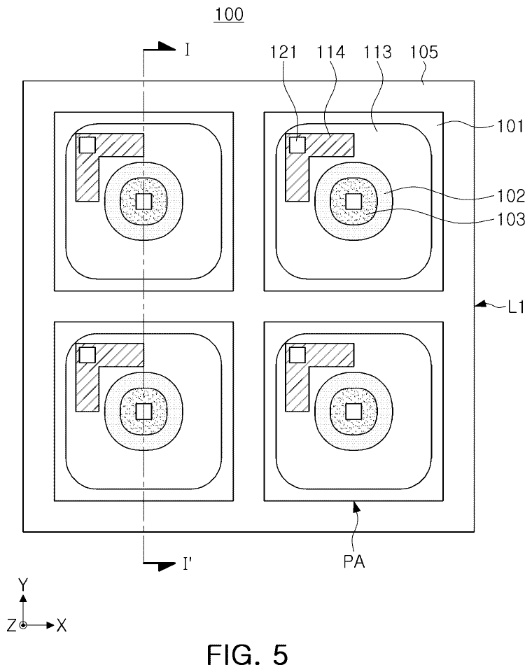

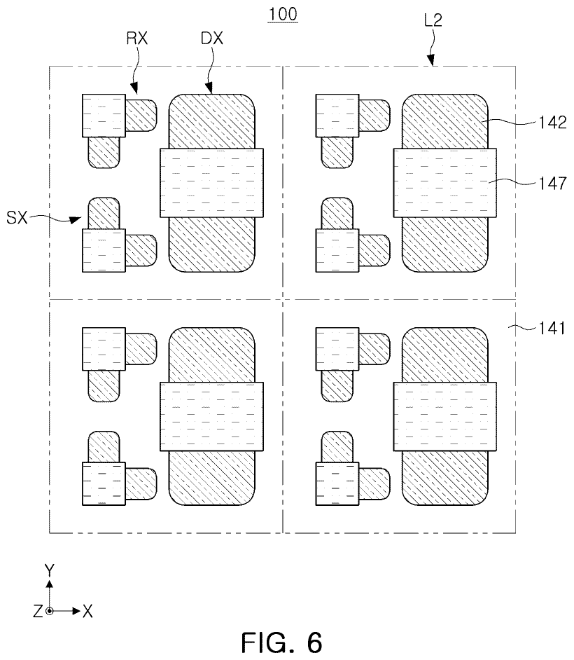

FIG. 5 is a view schematically illustrating a partial region of a first layer included in an image sensor, according to some embodiments consistent with the present disclosure. FIG. 6 is a view schematically illustrating a partial region of a second layer included in an image sensor, according to some embodiments consistent with the present disclosure.

As described above, in some embodiments, a pixel array of an image sensor may be provided by a first layer and a second layer, stacked on each other. Referring to the example of FIG. 5, a first layer L1, according to some embodiments, may include a first substrate 101, and a pixel isolation layer 105 may be formed in the first substrate 101. The pixel isolation layer 105 may extend in the first direction (e.g., X-axis direction) and the second direction (e.g., Y-axis direction) to define a plurality of pixel regions PA.

Referring further to the example of FIG. 5, an active region 102, a floating diffusion region 103, and transfer gates 113, 114 may be disposed in each of the plurality of pixel regions PA. Transfer gates 113, 114 may include a first gate region 113 buried in first substrate 101, and a second gate region 114 disposed on an upper surface of first gate region 113. In some embodiments, second gate region 114 may have a smaller area than first gate region 113 in, e.g., a plane parallel to the first and second directions, and therefore a portion of first gate region 113 may not be covered by second gate region 114. A contact 121 may be connected to floating diffusion region 103 and second gate region 114. Second gate region 114 is illustrated in FIG. 5 as having a region extending in the first direction and a region extending in the second direction, but it will be understood that a shape thereof is not necessarily limited thereto. Contact connected to second gate region 114 may be disposed on an edge region of first gate region 113, in the first direction and the second direction.

With further reference to FIG. 5 and embodiments based thereon, active region 102 may be disposed between floating diffusion region 103 and first gate region 113 in the first and second directions. In some embodiments, active region 102 and floating diffusion region 103 may be doped with impurities of the same conductivity type, for example, with N-type impurities. In some embodiments, an impurity doping concentration of floating diffusion region 103 may be higher than an impurity doping concentration of active region 102.

By implementing first layer L1 as illustrated in FIG. 5, a photodiode, floating diffusion region 103, and a transfer transistor may be implemented in each of the plurality of pixel regions PA. Remaining elements included in one pixel, such as, for example, a reset transistor RX, a drive transistor DX, and a select transistor SX, may be disposed on a second layer L2, as further illustrated in the example of FIG. 6.

Referring to FIG. 6, in some embodiments, a second layer L2 may include a plurality of transistors RX, DX, SX which comprise a pixel circuit. Second layer L2 may include a second substrate 141 which may be a separate substrate from first substrate 101 (shown in FIG. 5), and the plurality of transistors RX, DX, SX may comprise active regions 142 formed in second substrate 141, as well as gate structures 147.

In some embodiments, the plurality of transistors RX, DX, SX may be disposed in regions corresponding to a plurality of pixel regions PA of first layer L1. As shown in FIG. 6, as first layer L1 and second layer L2 are stacked, a reset transistor RX, a drive transistor DX, and a select transistor SX may be disposed, e.g., one by one.

In some embodiments, the reset transistor RX, the drive transistor DX, and the select transistor SX may be connected to a photodiode, to transfer gate 113, 114, and/or to floating diffusion region 103, disposed in one of the plurality of pixel regions PA in first layer L1, to provide one pixel. As illustrated in FIG. 6, a pixel isolation layer 105 may not be disposed between the regions of second layer L2 corresponding to each of the plurality of pixel regions PA, and a shallow trench isolation (STI) for isolating the reset transistor RX, the drive transistor DX, and the select transistor SX from each other may, instead, be formed in second substrate 141.

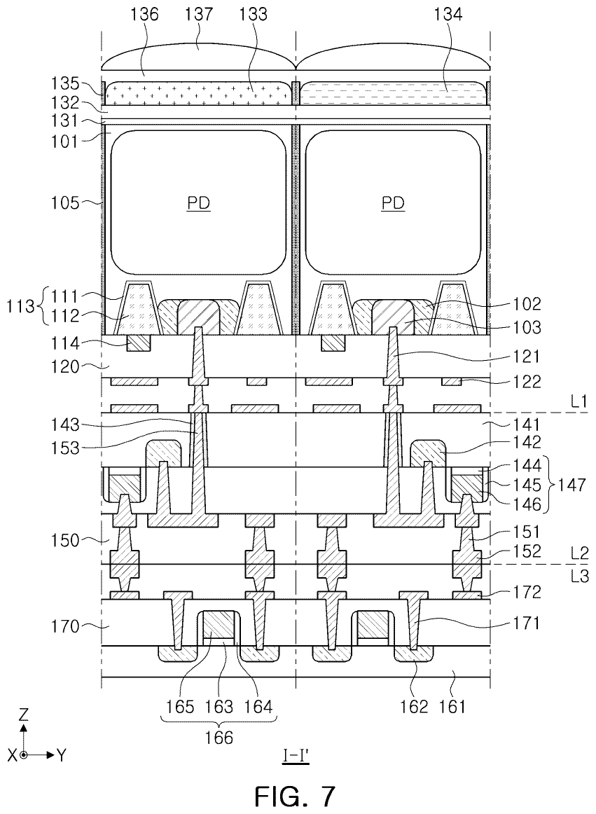

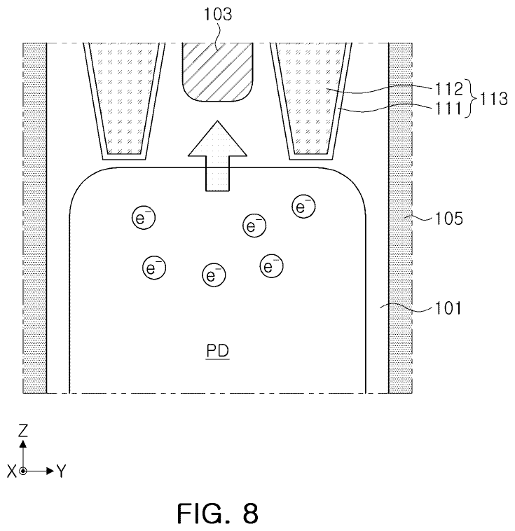

FIG. 7 is a cross-sectional view illustrating a cross-section of FIG. 5, taken along line I-I′, and FIG. 8 is an enlarged view of a partial region of FIG. 7, according to some embodiments.

Referring first to FIG. 7, an image sensor 100, according to some embodiments, may include first to third layers L1 to L3 stacked on each other. As previously described with reference to FIGS. 5 and 6, first layer L1 may include a plurality of pixel regions PA defined on a first substrate 101 in the first direction (e.g., X-axis direction) and the second direction (e.g., Y-axis direction), and the plurality of pixel regions PA may be separated from each other by a pixel isolation layer 105 formed in the first substrate 101. First to third layers L1 to L3 may be stacked on each other in a third direction (e.g., Z-axis direction) perpendicular to an upper surface of first substrate 101.

In some embodiments, pixel isolation layer 105 may be formed to penetrate first substrate 101 in, e.g., the third direction. Alternatively, in some embodiments, pixel isolation layer 105 may have a shape not completely penetrating first substrate 101 in the third direction. Pixel isolation layer 105 may include a plurality of layers comprising different materials, and may include, for example, a first pixel isolation layer contacting first substrate 101, and a second pixel isolation layer disposed on the first pixel isolation layer. In some embodiments, the first pixel isolation layer may comprise a material such as aluminum oxide or the like, the second pixel isolation layer may comprise a material such as silicon oxide or the like, and a void may exist in the second pixel isolation layer.

In some embodiments, a width of pixel isolation layer 105 in the third direction may or may not be constant. For example, pixel isolation layer 105 may have a relatively large width, in a region far from a first surface (e.g., a surface close to second layer L2) and a second surface (e.g., a surface far from second layer L2) of first substrate 101 in the third direction.

In some embodiments, a photodiode PD may be disposed in each of the plurality of pixel regions PA. In some embodiments, two or more photodiodes PD may be disposed in each of the plurality of pixel regions PA. Photodiode PD may be formed, e.g., by a process of injecting N-type impurities into first substrate 101.

In some embodiments, an active region 102, a floating diffusion region 103, and transfer gates 113 and 114 may be formed in a region close to the first surface of first substrate 101. Active region 102 and floating diffusion region 103 may be regions doped with N-type impurities, and an impurity concentration of floating diffusion region 103 may be higher than an impurity concentration of active region 102. As previously described with reference to FIG. 5, floating diffusion region 103 may have a shape surrounded by active region 102.

In some embodiments, transfer gates 113, 114 may be disposed around active region 102. Transfer gates 113, 114 may include a first gate region 113 buried in first substrate 101, and a second gate region 114 disposed on an upper surface of first gate region 113. First gate region 113 may include a gate insulating layer 111 and a first gate electrode layer 112, and gate insulating layer 111 may be disposed between first gate electrode layer 112 and first substrate 101. Second gate region 114 may include a second gate electrode layer, and first gate electrode layer 112 and the second gate electrode layer may comprise the same material. In some embodiments, first gate electrode layer 112 and the second gate electrode layer may comprise polysilicon, respectively.

In some embodiments, horizontal insulating layers 131, 132 may be disposed on the second surface of first substrate 101. Horizontal insulating layers 131, 132 may include a first horizontal insulating layer 131 and a second horizontal insulating layer 132, and first horizontal insulating layer 131 may comprise a material having a higher dielectric constant than second horizontal insulating layer 132. In some embodiments, first horizontal insulating layer 131 may extend from the first pixel isolation layer included in pixel isolation layer 105, and second horizontal insulating layer 132 may extend from the second pixel isolation layer included in pixel isolation layer 105.

In some embodiments, color filters 133, 134 may be disposed on horizontal insulating layers 131, 132, and a grid pattern 135 may be disposed between color filters 133, 134. Color filters 133, 134 may pass light in a specific wavelength band incident to a corresponding photodiode PD. For example, a first color filter 133 may pass light in a green wavelength band, and a second color filter 134 may pass light in a blue wavelength band. In some embodiments, a planarization layer 136 and a microlens 137 may be disposed on color filters 133, 134.

In some embodiments, first interconnection patterns 121, 122 and a first interlayer insulating layer 120 may be disposed on the first surface of first substrate 101. First interconnection patterns 121, 122 may be disposed in first interlayer insulating layer 120, and may include a plurality of contacts 121 connected to transfer gates 113, 114 and floating diffusion region 103.

In some embodiments, second layer L2 may include a second substrate 141, and active regions 142 may be formed in second substrate 141, and gate structures 147 may be formed on second substrate 141. In some embodiments, each of gate structures 147 may include a gate insulating layer 144, a gate spacer 145, and a gate electrode layer 146. Active regions 142 and gate structures 147 may provide a plurality of transistors RX, DX, SX for providing a pixel, as previously described with reference to FIG. 6. Active regions 142 and gate structures 147 may be connected to second interconnection patterns 151, 152 disposed in a second interlayer insulating layer 150.

In some embodiments, second interconnection patterns 151, 152 may include a plurality of contacts 151, and at least a portion of second interconnection patterns 151, 152 may be connected to via structures 153 penetrating second substrate 141. Since a substrate insulating layer 143 formed of an insulating material may be disposed between via structures 153 and second substrate 141, via structures 153 may not directly contact second substrate 141.

In some embodiments, via structures 153 may connect second interconnection patterns 151, 152 and first interconnection patterns 121, 122 to each other. Transfer gates 113, 114 and floating diffusion region 103, included in first layer L1, may be electrically connected to the plurality of transistors RX, DX, SX included in second layer L2, by via structures 153. For example, in each of the plurality of pixel regions PA, via structures 153 may electrically connect floating diffusion region 103 and second gate region 114 to the plurality of transistors RX, DX, SX. Therefore, pixels represented by an equivalent circuit, as previously described with reference to FIG. 3, may be provided by first layer L1 and second layer L2.

In some embodiments, third layer L3 may include a third substrate 161, and active regions 162 may be formed in third substrate 161, and gate structures 166 may be formed on third substrate 161. In some embodiments, each of gate structures 166 may include a gate insulating layer 163, a gate spacer 164, and a gate electrode layer 165. Active regions 162 and gate structures 166 may drive a plurality of pixels implemented in first layer L1 and second layer L2, to provide circuits for generating image data, for example, a row driver, a readout circuit, a data output circuit, a control logic, or the like.

In some embodiments, a third interlayer insulating layer 170 and third interconnection patterns 171, 172 may be disposed on third substrate 161. At least a portion of third interconnection patterns 171, 172 may be connected to a portion of second interconnection patterns 151, 152 disposed in second layer L2. For example, as illustrated in FIG. 7, a portion of second interconnection patterns 151, 152 and a portion of third interconnection patterns 171, 172 may be connected in a copper-to-copper (C2C) method.

As further illustrated in FIG. 7, in some embodiments, floating diffusion region 103 may be disposed on photodiode PD in the third direction in each of the plurality of pixel regions PA included in first layer L1, and first gate region 113 of transfer gates 113, 114 may be disposed around floating diffusion region 103. First gate region 113 may have a shape adjacent to as many regions as possible of floating diffusion region 103, and may have a shape completely surrounding floating diffusion region 103, for example. In the third direction, a depth of first gate region 113 may be greater than a depth of active region 102 and a depth of floating diffusion region 103. For example, in the third direction, a lowermost end portion of first gate region 113 buried in first substrate 101 may be disposed below a lowermost end portion of active region 102 and a lowermost end portion of floating diffusion region 103.

In this manner, floating diffusion region 103 may be disposed in a region close to a center of each of the plurality of pixel regions PA, and first gate region 113 may be disposed around floating diffusion region 103, to, e.g., improve movement efficiency of charges from photodiode PD to floating diffusion region 103.

Referring now to FIG. 8, in some embodiments, floating diffusion region 103 may be disposed on a region in which charges generated in a photodiode PD are concentrated at the highest density. Therefore, in some embodiments, when a turn-on voltage is applied to first gate region 113 to form a channel, the charges of photodiode PD may move to floating diffusion region 103 along a shortest path, and thus charge movement efficiency may be improved.

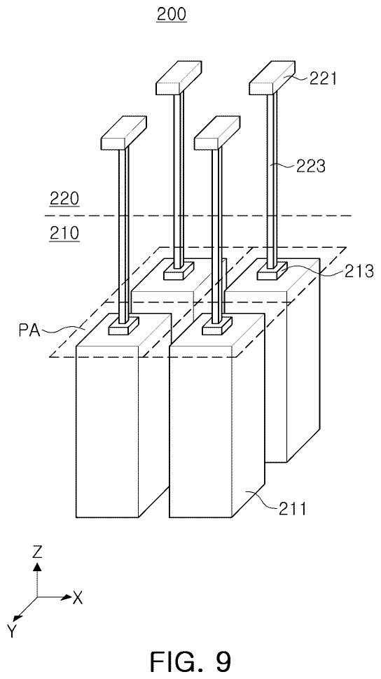

FIG. 9 is a view schematically illustrating a structure of an image sensor according to some embodiments consistent with the present disclosure.

Referring to FIG. 9, an image sensor 200 according to some embodiments may include a first layer 210 and a second layer 220. First layer 210 may include a plurality of pixel regions PA arranged in the first direction (e.g., X-axis direction) and the second direction (e.g., Y-axis direction), and a photodiode 211 and a floating diffusion region 213 may be disposed in each of the plurality of pixel regions PA. Floating diffusion region 213 may be disposed on photodiode 211 in the third direction (e.g., Z-axis direction), and may be disposed on a region close to a center of photodiode 211 in the first and second directions.

In some embodiments, floating diffusion region 213 of each of the plurality of pixel regions PA may be connected to an interconnection pattern 221 of second layer 220 through a via structure 223. Image sensor 200, according to some embodiments as illustrated in FIG. 9, may include pixels represented by an equivalent circuit, as previously described with reference to FIG. 3. Therefore, one photodiode (e.g., photodiode 211) formed in each of the plurality of pixel regions PA may match one floating diffusion region (e.g., floating diffusion region 213), and the one floating diffusion region may be connected to interconnection pattern 221 through via structure 223. In some embodiments, interconnection pattern 221 may be electrically connected to a plurality of transistors included in second layer 220. In some embodiments, via structure 223 may be a through silicon via (TSV) that penetrates a substrate included in second layer 220.

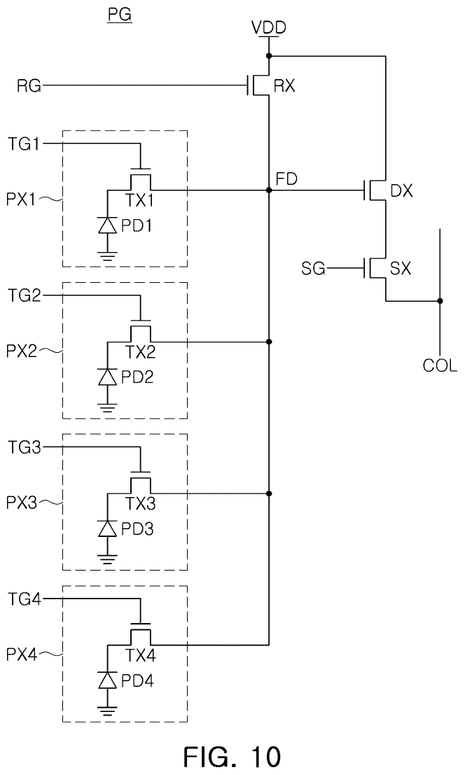

FIG. 10 is a view schematically illustrating a pixel circuit included in an image sensor according to some embodiments consistent with the present disclosure.

In some embodiments according to FIG. 10, two or more pixels PX1-PX4 may be included in one pixel group PG, and may share one floating diffusion region FD. Referring further to FIG. 10, in some embodiments, first to fourth pixels PX1-PX4 may be commonly connected to one floating diffusion region FD. In some embodiments, first pixel PX1 may include a first photodiode PD1 and a first transfer transistor TX1, second pixel PX2 may include a second photodiode PD2 and a second transfer transistor TX2, third pixel PX3 may include a third photodiode PD3 and a third transfer transistor TX3, and fourth pixel PX4 may include a fourth photodiode PD4 and a fourth transfer transistor TX4.

In some embodiments, one pixel group PG may include a reset transistor RX, a drive transistor DX, and a select transistor SX, one by one, and pixel group PG may further be connected to one column line COL. Therefore, in some embodiments, first to fourth pixels PX1-PX4 may share reset transistor RX, drive transistor DX, and select transistor SX.

In some embodiments, a readout operation for acquiring a pixel signal from each of the first to fourth pixels PX1-PX4 may be performed individually. For example, while a readout operation for first pixel PX1 is performed, second to fourth transfer transistors TX2-TX4 may maintain a turned-off state.

In some embodiments, a portion of components respectively included in pixels (e.g., PX1-PX4) may be distributed and disposed in first and second layers L1 and L2, stacked on each other. Referring to FIG. 3, in some embodiments, in each of pixels PX, a photodiode PD, a transfer transistor TX, and a floating diffusion region FD may be disposed on first layer L1, and a reset transistor RX, a drive transistor DX, and a select transistor SX may be disposed on second layer L2. In some embodiments, a contact structure and a via structure may be connected to floating diffusion region FD, and reset transistor RX and drive transistor DX may be connected to the via structure.

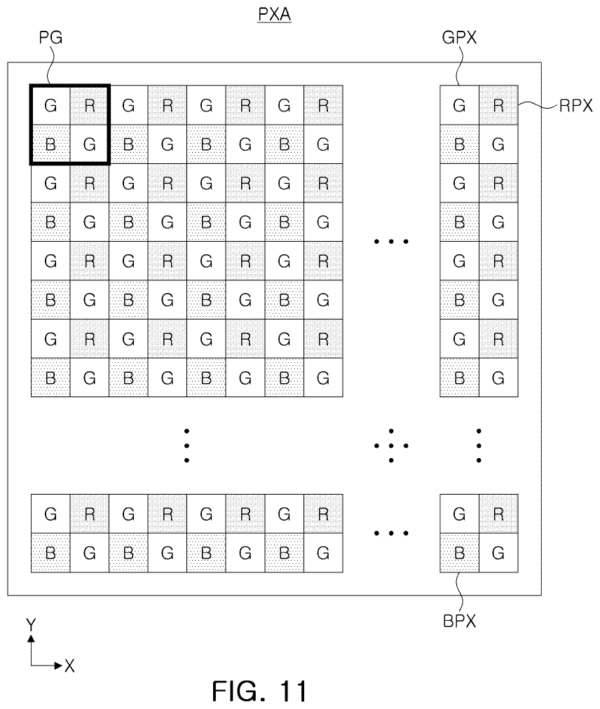

FIG. 11 is a view schematically illustrating a pixel array included in an image sensor according to some embodiments consistent with the present disclosure.

Referring to FIG. 11, a pixel array PXA included in an image sensor according to some embodiments may include a plurality of pixels arranged in the first direction (e.g., X-axis direction) and the second direction (e.g., Y-axis direction). The plurality of pixels may be divided into red pixels RPX, green pixels GPX, and blue pixels BPX, depending on a type of color filter included in each of the pixels. In some embodiments, the plurality of pixels may include a white pixel not filtering light in a specific wavelength band, or the like.

In some embodiments according to FIG. 11, two or more pixels adjacent to each other in pixel array PXA may be included in one pixel group (e.g., pixel group PG). For example, four pixels arranged in a 2×2 shape may be included in pixel group PG, and pixel group PG may include one red pixel RPX, one blue pixel BPX, and two green pixels GPX. As a further example, in pixel group PG, green pixels GPX may be arranged in a first diagonal direction, and red pixels RPX and blue pixels BPX may be arranged in a second diagonal direction intersecting the first diagonal direction.

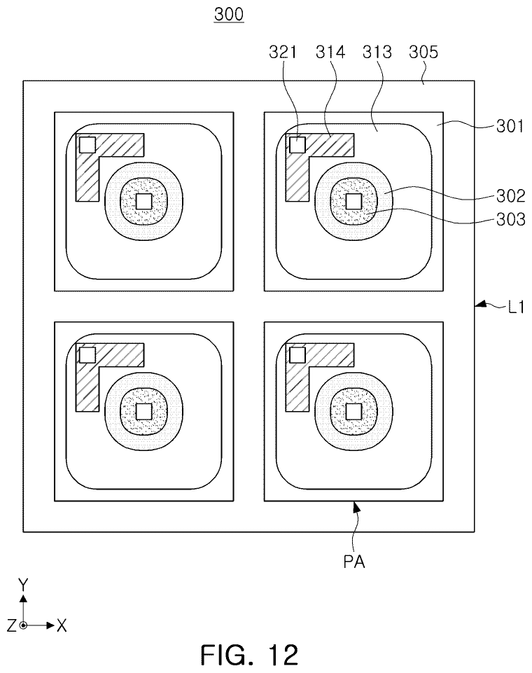

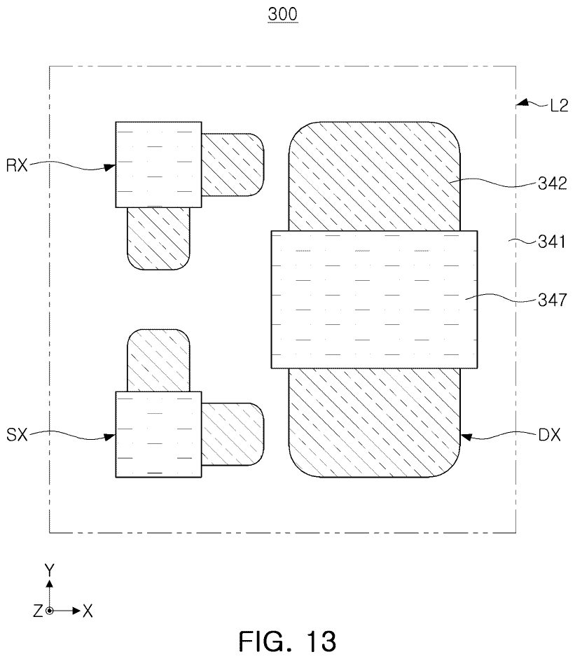

FIGS. 12 and 13 are views schematically illustrating a partial region of a first layer and a partial region of a second layer included in an image sensor according to some embodiments consistent with the present disclosure.

In some embodiments, components respectively included in pixels included in an image sensor 300 may be distributed and disposed on a first layer L1 and a second layer L2, stacked on each other. Referring to FIG. 12, first layer L1, according to some embodiments, may include a first substrate 301, and a pixel isolation layer 305 may be formed in first substrate 301. In some embodiments, pixel isolation layer 305 may extend in the first direction (e.g., X-axis direction) and the second direction (e.g., Y-axis direction) to define a plurality of pixel regions PA.

Referring further to FIG. 12, in some embodiments, a structure of each of the plurality of pixel regions PA may be similar to that structure previously described with reference to FIG. 5. For example, an active region 302, a floating diffusion region 303, and transfer gates 313, 314 may be disposed in each of the plurality of pixel regions PA. Transfer gates 313, 314 may include a first gate region 313 buried in first substrate 301 and a second gate region 314 disposed on an upper surface of first gate region 313. In some embodiments, a contact 321 may be connected to floating diffusion region 303 and second gate region 314.

In some embodiments, active region 302 may be disposed between floating diffusion region 303 and first gate region 313 in the first and second directions, and active region 302 and floating diffusion region 303 may be doped with impurities of the same conductivity type. In some embodiments, an impurity doping concentration of floating diffusion region 303 may be higher than an impurity doping concentration of active region 302.

In some embodiments, by implementing first layer L1 as illustrated in FIG. 12, floating diffusion region 303 may be disposed close to a region having the highest charge density of the photodiode in each of the plurality of pixel regions PA. Therefore, in some embodiments, while a channel is formed by a turn-on voltage applied to transfer gates 313, 314, charges of the photodiode may efficiently move to floating diffusion region 303.

In some embodiments according to FIG. 12, floating diffusion regions 303 included in pixel regions PA arranged in a 2×2 shape may be electrically connected to each other in first layer L1, or in second layer L2 stacked on first layer L1. Additionally, in some embodiments, floating diffusion regions 303 may be electrically connected to a reset transistor RX, a select transistor SX, and a drive transistor DX, disposed on second layer L2, as illustrated in FIG. 13. Therefore, as described with reference to embodiments according to FIG. 10, one pixel group PG including four photodiodes PD1-PD4, four transfer transistors TX1-TX4, a reset transistor RX, a select transistor SX, and a drive transistor DX may be provided by first layer L1 and second layer L2.

In some embodiments, second layer L2 may include a second substrate 341, which may be a separate substrate from first substrate 301, and a plurality of transistors RX, DX, SX may be provided by active regions 342 formed in second substrate 341, as well as gate structures 347. For example, the plurality of transistors RX, DX, SX may be disposed in a region corresponding to a plurality of pixel regions PA included in one pixel group (e.g., pixel group PG) in first layer L1.

In some embodiments, since four photodiodes PD1-PD4 and four transfer transistors TX1-TX4 share a reset transistor RX, a select transistor SX, and a drive transistor DX in one pixel group PG, a size of the reset transistor RX, a size of the select transistor SX, and a size of the drive transistor DX may increase, as illustrated in FIG. 13. For example, as illustrated in FIG. 13, signal-to-noise ratio (SNR) characteristics of the pixel may be improved by forming drive transistor DX to a sufficient size or, e.g., by forming two drive transistors DX. Alternatively, various additional functions, for example, a function of changing conversion gain, may be implemented by forming at least one switch transistor, in addition to reset transistor RX, select transistor SX, and drive transistor DX.

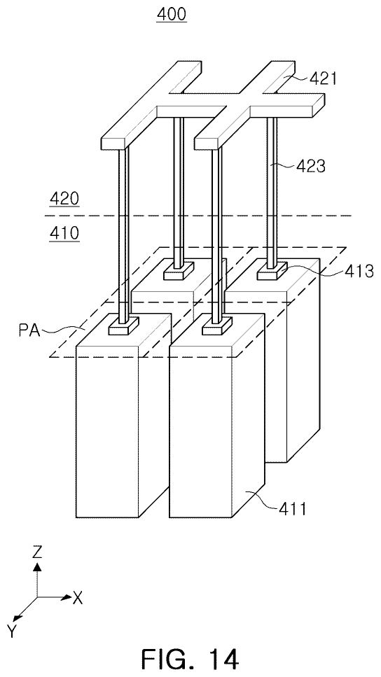

FIG. 14 is a view schematically illustrating a structure of an image sensor according to some embodiments consistent with the present disclosure.

Referring to FIG. 14, an image sensor 400 according to some embodiments may include a first layer 410 and a second layer 420. First layer 410 may include a plurality of pixel regions PA arranged in the first direction (e.g., X-axis direction) and the second direction (e.g., Y-axis direction), and a photodiode 411 and a floating diffusion region 413 may be disposed in each of the plurality of pixel regions PA. In some embodiments, floating diffusion region 413 may be disposed on photodiode 411 in the third direction (e.g., Z-axis direction), and may be disposed on a region close to a center of photodiode 411 in the first and second directions.

In some embodiments, floating diffusion region 413 of each of the plurality of pixel regions PA may be connected to an interconnection pattern 421 of second layer 420 through a via structure 423. Image sensor 400 according to some embodiments as illustrated in FIG. 14 may include pixels represented by an equivalent circuit, as previously described with reference to FIG. 10. Therefore, in some embodiments, four floating diffusion regions 413 arranged in four pixel regions PA arranged in a 2×2 shape may be electrically connected to each other by interconnection pattern 421, and in circuit terms, one floating diffusion region may exist in one pixel group, as illustrated in FIG. 11.

In some embodiments, among transistors disposed in second layer 420, a reset transistor RX, a drive transistor DX, and a select transistor SX, disposed in a region overlapping four pixel regions PA arranged in a 2×2 shape in first layer 410, may be connected to interconnection pattern 421. Therefore, in some embodiments, four photodiodes 411 and four transfer transistors, arranged in four pixel regions PA arranged in a 2×2 shape in first layer 410, may share reset transistor RX, drive transistor DX, and select transistor SX, to implement pixels and pixel groups.

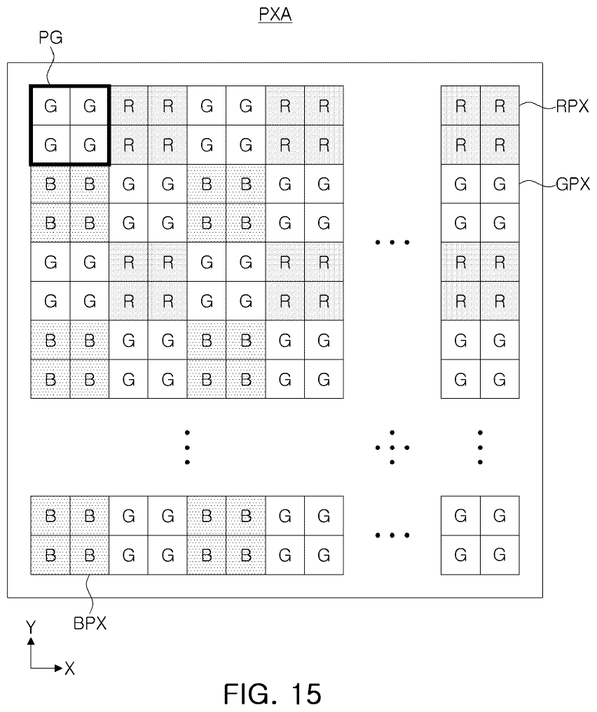

FIG. 15 is a view schematically illustrating a pixel array included in an image sensor according to some embodiments consistent with the present disclosure.

Referring to FIG. 15, a pixel array PXA included in an image sensor according to some embodiments may include a plurality of pixels arranged in the first direction (e.g., X-axis direction) and the second direction (e.g., Y-axis direction). The plurality of pixels may be divided into red pixels RPX, green pixels GPX, and blue pixels BPX, depending on a type of color filter included in each of the pixels. Depending on some embodiments, the plurality of pixels may include a white pixel not filtering light in a specific wavelength band, or the like.

In pixel array PXA, according to some embodiments as illustrated in FIG. 15, two or more pixels adjacent to each other in pixel array PXA may be included in one pixel group PG. For example, four pixels arranged in a 2×2 shape may be included in one pixel group PG, and pixels included in one pixel group PG may include a color filter of the same color. For example, one pixel group PG may include four green pixels GPX, four red pixels RPX, or four blue pixels BPX. In some embodiments, four pixels included in one pixel group PG may share one microlens.

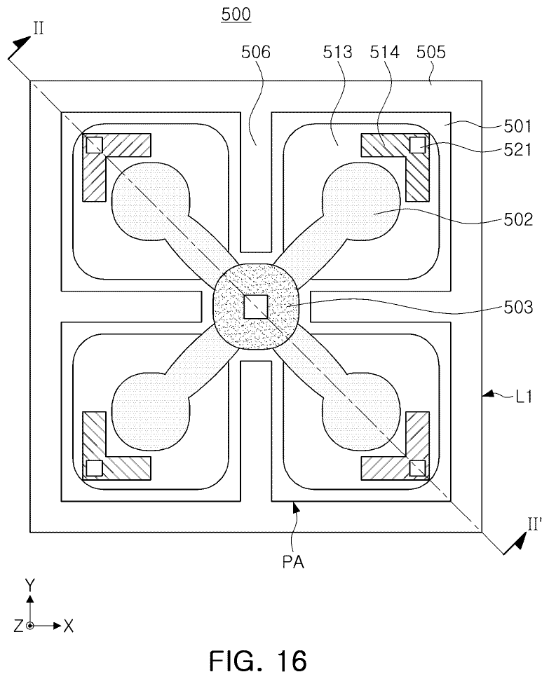

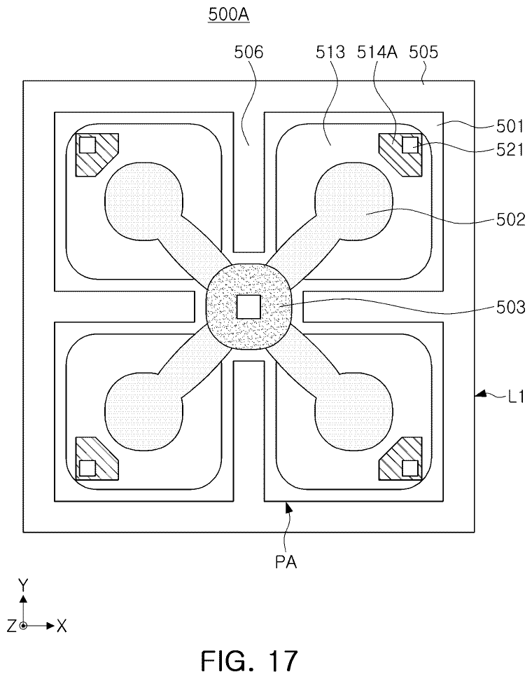

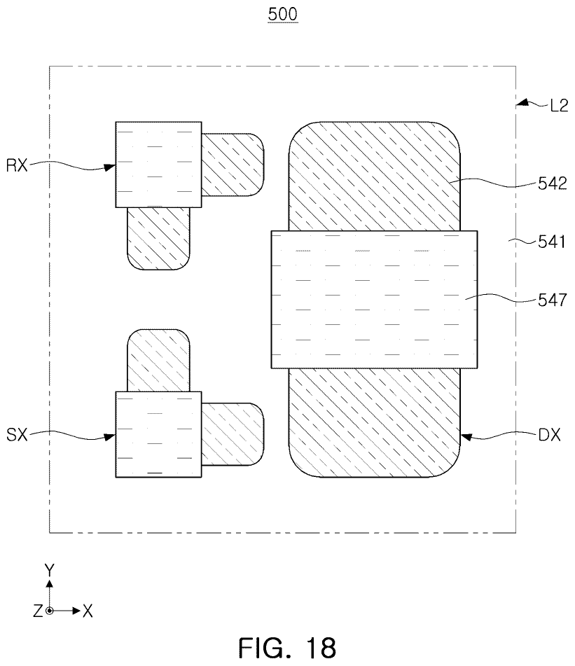

FIGS. 16 and 17 are views schematically illustrating a partial region of a first layer included in an image sensor according to some embodiments consistent with the present disclosure. FIG. 18 is a view schematically illustrating a partial region of a second layer included in an image sensor according to some embodiments consistent with the present disclosure.

Referring to FIGS. 16 and 17, a first layer L1 of an image sensor 500, 500A, according to some embodiments, may include a first substrate 501, and pixel isolation layers 505, 506 may be formed on first substrate 501. In some embodiments, pixel isolation layers 505 and 506 may extend in the first direction (e.g., X-axis direction) and the second direction (e.g., Y-axis direction) to define a plurality of pixel regions PA. In some embodiments, a photodiode may be formed in each of the plurality of pixel regions PA, and thus a photodiode array may be implemented in first layer L1.

As illustrated in FIGS. 16 and 17, in some embodiments, an active region 502 and transfer gates 513, 514, 514A may be disposed in each of the plurality of pixel regions PA. In some embodiments, transfer gates 513, 514, 514A may include a first gate region 513 buried in first substrate 501, and a second gate region 514, 514A disposed on an upper surface of first gate region 513.

In the embodiments illustrated in FIGS. 16 and 17, second gate region 514, 514A may have different shapes. In some embodiments according to FIG. 16, second gate region 514 may include a region extending in the first direction and a region extending in the second direction. In some embodiments as illustrated in FIG. 17, second gate region 514A may have a polygonal shape.

In the embodiments illustrated in FIGS. 16 and 17, four pixel regions PA arranged in the first and second directions may provide one pixel group PG. As previously described with reference to FIG. 10 and the like, one pixel group PG may include one floating diffusion region 503, and floating diffusion region 503 may be shared by photodiodes and transfer transistors, implemented in four pixel regions PA.

In some embodiments, floating diffusion region 503 may be disposed in a central portion of the four pixel regions PA included in pixel group PG. Referring to FIGS. 16 and 17, in some embodiments, pixel isolation layers 505, 506 may include an external pixel isolation layer 505 disposed along a boundary of a pixel group PG including four pixel regions PA, and internal pixel isolation layers 506 disposed between the four pixel regions PA in the pixel group PG.

In some embodiments, internal pixel isolation layers 506 may be formed of the same material as external pixel isolation layer 505, or they may be formed of a different material. In some embodiments, pixel isolation layers 505, 506 may penetrate first substrate 501 in the third direction (e.g., Z-axis direction), perpendicular to an upper surface of first substrate 501. Alternatively, external pixel isolation layer 505 may penetrate first substrate 501 in the third direction, and internal pixel isolation layer 506 may not penetrate first substrate 501 in the third direction. Alternatively, pixel isolation layers 505, 506 may not penetrate first substrate 501 in the third direction. In some embodiments, internal pixel isolation layers 506 may not completely separate the four pixel regions PA, and, in a region in which the pixel groups PG are disposed, internal pixel isolation layers 506 may not be formed in a region close to a corner in which the four pixel regions PA are gathered. Therefore, as illustrated in FIGS. 16 and 17, in some embodiments, a length of each of internal pixel isolation layers 506 in the first or second direction may be shorter than a length of external pixel isolation layer 505.

In some embodiments, floating diffusion region 503 may be formed in a region in which internal pixel isolation layer 506 is not formed, in a region in which the pixel group PG is disposed. Therefore, in some embodiments, distances between floating diffusion region 503 and each of active regions 502 formed in the four pixel regions PA may be substantially the same, and distances in which charges of each of the photodiodes formed in the four pixel regions PA move to floating diffusion region 503 may also be substantially the same.

In some embodiments, four internal pixel isolation layers 506 may include a pair (e.g., a first pair) of internal pixel isolation layers 506 adjacent to each other in the first direction, and a different pair (e.g., a second pair) of internal pixel isolation layers 506 adjacent to each other in the second direction. In some embodiments, floating diffusion region 503 may be disposed between a pair (e.g., a first pair) of adjacent internal pixel isolation layers 506 in the first direction, and between a different pair (e.g., a second pair) of adjacent internal pixel isolation layers 506 in the second direction.

In some embodiments, active region 502 may be disposed close to centers of each of the pixels region PA, and first gate region 513 buried in first substrate 501 may be disposed around active region 502. In some embodiments, first gate region 513 may be formed to surround a possible region of active region 502, except for a region in which active region 502 and floating diffusion region 503 are connected.

In addition, in some embodiments, active region 502 may be formed at a position close to the centers of each of the pixel regions PA, to dispose active region 502 close to a region having the highest charge density in the photodiode of each of the pixel regions PA. In this manner, by increasing an area in which first gate region 513 and active region 502 face each other and disposing active region 502 near a region having the highest charge density in the photodiode, according to some embodiments, charges generated in the photodiode may improve efficiency of moving to floating diffusion region 503.

In some embodiments, a contact 521 may be connected to floating diffusion region 503 and second gate region 514, 514A. Referring to FIGS. 17 and 18, in some embodiments, floating diffusion region 503 and second gate region 514, 514A may be connected to interconnection patterns of first layer L1 through contact 521, and floating diffusion region 503 may be connected to at least a portion of a plurality of transistors RX, SX, DX formed in second layer L2.

Referring to FIG. 18, in some embodiments, a plurality of transistors RX, SX, DX may be disposed in a partial region of a second layer L2 that matches a region in which one pixel group PG is disposed. In some embodiments, the plurality of transistors RX, SX, DX may include a reset transistor RX, a drive transistor DX, and a select transistor SX. The plurality of transistors RX, SX, DX may be provided by active regions 542 formed in a second substrate 541, as well as a gate structure 547.

In some embodiments, reset transistor RX, drive transistor DX, and select transistor SX may be electrically connected to photodiodes, transfer gates 513, 514, 514A, and floating diffusion region 503, disposed in pixel regions PA included in one pixel group PG in a first layer L1. In some embodiments, the pixel group PG may be implemented via a circuit, as illustrated in FIG. 10. In some embodiments, the plurality of transistors RX, SX, DX may be formed in a region of second substrate 541 corresponding to four pixel regions PA, to e.g., improve SNR characteristics of an image sensor 500. Alternatively, additional functions of image sensor 500 may also be implemented by forming an additional transistor, in addition to the plurality of transistors RX, SX, DX in the region of second substrate 541 corresponding to the four pixel regions PA.

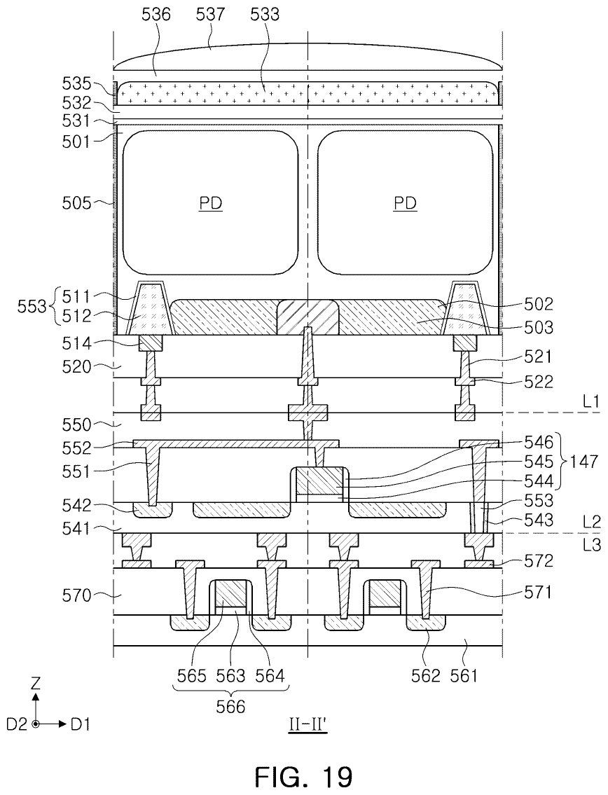

FIG. 19 is a cross-sectional view illustrating a cross-section of FIG. 16, taken along line II-II′.

Referring to FIG. 19, an image sensor (e.g., image sensor 500 of FIG. 16), according to some embodiments, may include first to third layers L1-L3, stacked on each other. First layer L1 may include a plurality of pixel regions PA arranged on a first substrate 501 in the first direction (e.g., X-axis direction) and the second direction (e.g., Y-axis direction), as illustrated in FIGS. 16 and 17, and the plurality of pixel regions PA may be separated from each other by an external pixel isolation layer 505 formed in first substrate 501. In some embodiments, first to third layers L1-L3 may be stacked on each other in the third direction (e.g., Z-axis direction), perpendicular to an upper surface of first substrate 501.

Referring further to FIG. 19, in some embodiments, external pixel isolation layer 505 may penetrate first substrate 501 in the third direction. In some embodiments, external pixel isolation layer 505 may not completely penetrate first substrate 501 in the third direction, and in this case, external pixel isolation layer 505 may separate a first surface and a second surface of first substrate 501. Hereinafter, the first surface may be a surface close to second layer L2, and the second surface may be a surface far away from second layer L2. External pixel isolation layer 505 may include a plurality of layers comprising different materials, and may have a structure similar to pixel isolation layer 105 in the embodiment previously described with reference to FIG. 7.

As illustrated in FIGS. 16 and 17, in some embodiments, four pixel regions PA arranged in a 2×2 shape in the first and second directions may be included in one pixel group PG, and one floating diffusion region (e.g., floating diffusion region 503) may be included in the one pixel group PG. In some embodiments, a photodiode PD, transfer gates 513, 514, and an active region 502 may be disposed in each of the four pixel regions PA, and active region 502 may extend in a first diagonal direction D1 or a second diagonal direction D2, to be connected to floating diffusion region 503. In some embodiments, floating diffusion region 503 may be disposed in a region close to a center of the pixel group PG to be symmetrically connected to an active region of each of the four pixel regions PA. As illustrated in FIGS. 16 and 17, floating diffusion region 503 may be disposed between internal pixel isolation layers 506 in the first and second directions.

In some embodiments, although an internal pixel isolation layer (e.g., internal pixel isolation layer 506) is not illustrated in FIG. 19, taken along line II-II′, such an internal pixel isolation layer may penetrate first substrate 501, like an external pixel isolation layer 505, to contact the first and second surfaces of first substrate 501. In some embodiments, the internal pixel isolation layer may have a shorter length than external pixel isolation layer 505 in the third direction. For example, the internal pixel isolation layer may be in contact with the second surface of first substrate 501, and may be separated from the first surface of first substrate 501. Alternatively, in some embodiments, both the internal pixel isolation layer (e.g., internal pixel isolation layer 506) and external pixel isolation layer 505 may contact the second surface of first substrate 501, and may be separated from the first surface of first substrate 501. In some embodiments, on the second surface of first substrate 501, a width of external pixel isolation layer 505 may be substantially the same as a width of the internal pixel isolation layer.

In some embodiments, the photodiode PD, active region 502, and floating diffusion region 503 may be formed by a process of injecting N-type impurities into first substrate 501. As an example, an impurity concentration of active region 502 may be lower than an impurity concentration of floating diffusion region 503.

In some embodiments, transfer gates 513, 514 may include a first gate region 513 buried in first substrate 501, and a second gate region 514 disposed on an upper surface of first gate region 513, and first gate region 513 may include a gate insulating layer 511 and a first gate electrode layer 512. In some embodiments, gate insulating layer 511 may be disposed between first substrate 501 and first gate electrode layer 512, and a second gate electrode layer of second gate region 514 may comprise the same material as first gate electrode layer 512, for example, polysilicon. In some embodiments, the second gate electrode layer may comprise a different material from first gate electrode layer 512.

In some embodiments, since active region 502 and floating diffusion region 503 may be connected in the first diagonal direction D1 or the second diagonal direction D2, transfer gates 513, 514 may have a shape that surrounds a remaining region of active region 502, excluding, e.g., some regions connected to floating diffusion region 503. For example, as illustrated in FIGS. 16 and 17, first gate region 513 in each of the pixel regions PA may have an opening in the first diagonal direction D1 or in the second diagonal direction D2. In some embodiments, active region 502 and floating diffusion region 503 may be connected to each other at such an opening of first gate region 513. For example, active region 502 may be disposed in a central region of each of the pixel regions PA, and first gate region may cover more than 70% of the central region in each of the pixel regions PA, in a plan view. The plan view may be defined as a direction looking at a plane parallel to the first direction and the second direction. In some embodiments, first gate region 513 may cover more than 85% of the central region in the plan view. It means that an opening of first gate region 513 is less than 15% of a length surrounding the central region. Also, in some embodiments, first gate region 513 may cover more than 95% of the central region in the plan view.

Therefore, according to some embodiments, in each of the plurality of pixel regions PA, active region 502 may be disposed between first gate regions 513 in the first direction. Additionally, in some embodiments, active region 502 may be disposed between first gate regions 513 in the first diagonal direction D1 or the second diagonal direction D2. For example, in some embodiments as illustrated in FIGS. 16 and 17, in a pixel region PA located in an upper left end portion, an active region 502 may be disposed between first gate regions 513 in the second diagonal direction D2. As another example, in a pixel region PA located in an upper right end portion, an active region 502 may be disposed between first gate regions 513 in the first diagonal direction D1.

In some embodiments, when a turn-on voltage is applied to transfer gates 513, 514 to form a channel in first substrate 501, charges generated in the photodiode PD may move through active region 502 to floating diffusion region 503. As illustrated in FIG. 19, in some embodiments, since active region 502 may be formed on a region including a center of the photodiode PD, active region 502 may be disposed on a region in which a charge density is highest in the photodiode PD. Therefore, in some embodiments, movement efficiency of charges from the photodiode PD to floating diffusion region 503 may be improved.

In some embodiments, horizontal insulating layers 531, 532 may be disposed on the second surface of first substrate 501. In some embodiments, horizontal insulating layers 531, 532 may include a first horizontal insulating layer 531 and a second horizontal insulating layer 532 comprising a material having a lower dielectric constant than first horizontal insulating layer 531. In some embodiments, first horizontal insulating layer 531 may extend from one layer among a plurality of layers included in pixel isolation layer 505, and second horizontal insulating layer 532 may extend from a different layer among the plurality of layers included in pixel isolation layer 505.

In some embodiments, a color filter 533 may be disposed on horizontal insulating layers 531, 532. In some embodiments as illustrated in FIG. 19, one color filter 533 may be included in one pixel group PG, and therefore light of the same color may be incident to the photodiodes PD disposed in the four pixel regions PA. In some embodiments, color filter 533 may be separated from other adjacent colors by a grid pattern 535, and a planarization layer 536 and a microlens 537 may be disposed on color filter 533. As illustrated in FIG. 19, in some embodiments, one pixel group PG may include one microlens 537.

In some embodiments, first interconnection patterns 521, 522 and a first interlayer insulating layer 520 may be disposed on the first surface of first substrate 501. In some embodiments, first interconnection patterns 521, 522 may be disposed in first interlayer insulating layer 520, and may include a plurality of contacts 521 connected to transfer gates 513, 514 and floating diffusion region 503. For example, the plurality of contacts may be disposed on an edge region of first gate region 513, in the plan view.

In some embodiments, second layer L2 may include a second substrate 541, and active regions 542 and gate structures 547 may be formed in second substrate 541. In some embodiments, active regions 542 and gate structures 547 may be connected to second interconnection patterns 551, 552 disposed in a second interlayer insulating layer 550, and at least a portion of second interconnection patterns 551, 552 may be connected to at least a portion of first interconnection patterns 521, 522 in a C2C manner. In some embodiments, active regions 542 and gate structures 547 may provide a plurality of transistors RX, DX, SX connected to floating diffusion region 503.

In some embodiments, at least a portion of second interconnection patterns 551, 552 may be connected to via structures 553 penetrating second substrate 541. In some embodiments, a substrate insulating layer 543 formed of an insulating material may be disposed between via structures 553 and second substrate 541, such that, e.g., via structures 553 may not be in direct contact with and may be electrically separated from second substrate 541.

In some embodiments, via structures 553 may electrically connect second interconnection patterns 551, 552 to third interconnection patterns 571, 572 of a third layer L3. In some embodiments, third layer L3 may include a third substrate 561, a third interlayer insulating layer 570, and the like, and third interconnection patterns 571, 572 may be disposed in third interlayer insulating layer 570, and may be connected to active regions 562 and gate structures 566. In some embodiments, each of gate structures 566 may include a gate insulating layer 563, a gate spacer 564, and a gate electrode layer 565. In some embodiments, active regions 562 and gate structures 566 may drive a plurality of pixels implemented in first layer L1 and second layer L2, to provide circuits for generating image data, for example, a row driver, a readout circuit, a data output circuit, a control logic, or the like.

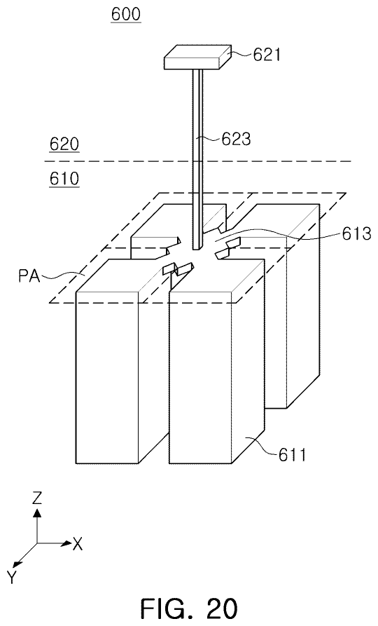

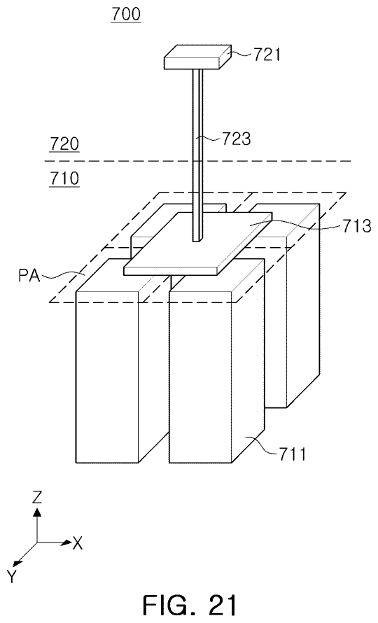

FIGS. 20 and 21 are views schematically illustrating a structure of an image sensor according to some embodiments consistent with the present disclosure.

Referring to FIG. 20, an image sensor (e.g., image sensor 600), according to some embodiments, may include a first layer 610 and a second layer 620, stacked on each other. In some embodiments, first layer 610 may include a plurality of pixel regions PA arranged in the first direction (e.g., X-axis direction) and the second direction (e.g., Y-axis direction), and a photodiode 611 may be disposed in each of the plurality of pixel regions PA. In some embodiments, a floating diffusion region 613 may be disposed in a region including a center of a pixel group including the pixel regions PA.

Therefore, as illustrated in FIG. 20, according to some embodiments, one floating diffusion region (e.g., floating diffusion region 613) may be shared by photodiodes 611 distributed in the pixel regions PA, and photodiodes 611 may be commonly connected to floating diffusion region 613. In some embodiments, to increase movement efficiency of charges from each of photodiodes 611 to floating diffusion region 613, an impurity region may be formed on a region having the highest charge density in each of photodiodes 611, and the impurity region may be connected to floating diffusion region 613. In some embodiments, in the impurity region, a transfer gate may be formed to surround a remaining region excluding, e.g., a region connected to floating diffusion region 613.

In some embodiments, floating diffusion region 613 may be connected to an interconnection pattern 621 of second layer 620 through a via structure 623. In some embodiments, interconnection pattern 621 may be connected to floating diffusion region 613, and may be connected to a drive transistor, a reset transistor, and a select transistor, providing a pixel circuit.

Referring to FIG. 21, an image sensor (e.g., image sensor 700), according to some embodiments, may include a first layer 710 and a second layer 720, stacked on each other. In some embodiments, first layer 710 may include a plurality of pixel regions PA arranged in the first direction (e.g., X-axis direction) and the second direction (e.g., Y-axis direction), and a photodiode 711 may be disposed in each of the plurality of pixel regions PA.

In some embodiments as illustrated in FIG. 21, a floating diffusion region may be formed in each of the plurality of pixel regions PA, and floating diffusion regions may be connected in first layer 710 through interconnection pattern 713. In some embodiments, interconnection pattern 713 may be connected to interconnection pattern 721 of second layer 720 through via structure 723, and may be connected to a drive transistor, a reset transistor, and a select transistor, providing a pixel circuit. In some embodiments, a transfer gate in first layer 710 may be formed in a shape that completely surrounds the floating diffusion region in each of the plurality of pixel regions PA.

According to some embodiments, a floating diffusion region and/or an active region connected to the floating diffusion region may be disposed above a region of a photodiode having the highest charge density, and a shape of a transfer gate may be formed to surround (at least partially) the floating diffusion region and/or the active region connected to the floating diffusion region. Therefore, according to some embodiments, performance of an image sensor may be improved by, e.g., minimizing loss of charges that may occur while the charges move from the photodiode to the floating diffusion region.

Various advantages and effects consistent with the present disclosure are not limited to the above-described contents, and can be more easily understood through description of specific embodiments.

While example embodiments have been illustrated and described above, it will be apparent to those skilled in the art that modifications and variations could be made without departing from the scope of the present disclosure as defined by the appended claims.

What is claimed is:

1. An image sensor comprising:
a first layer comprising:
a first substrate comprising a first surface and a second surface opposing the first surface;
a first pixel region comprising a first photodiode (PD) and a first transfer transistor;
a second pixel region comprising a second PD and a second transfer transistor;
a floating diffusion region shared by the first and second PDs; and
a common color filter on the second surface and covering the first pixel region and the second pixel region,
wherein the first transfer transistor comprise a first portion extended into the first substrate from the first surface and a second portion disposed on the first surface,
wherein the first portion surrounds a central region of the first pixel region in a plan view and covering more than 70% of the central region in the plan view, and
wherein the floating diffusion region is disposed in the first pixel region and the second pixel region.

2. The image sensor of claim 1, wherein the first portion covers more than 85% of the central region in the plan view.

3. The image sensor of claim 2, wherein the first portion covers more than 95% of the central region in the plan view.

4. The image sensor of claim 2, further comprising:
third pixel region comprising a third PD; and
a fourth pixel region comprising a fourth PD,
wherein the first to the fourth pixel regions are arranged in a 2×2 shape in a first direction and a second direction, parallel to the first surface of the first substrate and intersecting each other, and
wherein the floating diffusion region is shared by the first to the fourth PDs.

5. The image sensor of claim 4, wherein the first portion is continuously connected without any interruptions.

6. The image sensor of claim 5, wherein a disconnected part of the first portion, when viewed in the plan view, is in a direction from the central region toward the floating diffusion region.

7. The image sensor of claim 5, further comprising:
an isolation layer separating the first pixel region and the second pixel region, and
wherein the isolation layer is in contact with the first surface and the second surface.

8. The image sensor of claim 7, wherein the floating diffusion region is disposed in the first to the fourth pixel regions.

9. The image sensor of claim 8, further comprising:
a contact connected to the second portion, and
wherein the contact is disposed on an edge region of the first portion in the plan view.

10. The image sensor of claim 8, further comprising:
a second layer on the first layer, and
wherein the second layer comprises a plurality of transistors.

11. The image sensor of claim 10, wherein the plurality of transistors comprises a drive transistor and a select transistor.

12. The image sensor of claim 10, wherein the second layer is spaced apart from the first surface in a third direction perpendicular to the first surface.

13. The image sensor of claim 10, further comprising:
a third layer on the second layer, and
wherein the third layer comprises a second substrate and a plurality of transistors.

14. The image sensor of claim 10, wherein the first portion has a circle shape with an open portion.

15. The image sensor of claim 10, wherein the first portion has a closed circle shape.

16. An image sensor comprising:
a first layer comprising a first substrate comprising a first surface, a second surface opposing to the first surface, and first to fourth pixel regions;
a common color filter on the second surface and covering the first to fourth pixel regions; and
a floating diffusion region,
wherein each of the first to the fourth pixel regions comprises a photodiode (PD) and a transfer transistor,
wherein the floating diffusion region is surrounded by the first to fourth pixel regions in a plan view and shared by the first to the fourth PDs,
wherein the transfer transistor comprises a first portion extended into the first substrate from the first surface and a second portion disposed on the first surface, and
wherein the first portion surrounds a central region of each of the first to the fourth pixel regions in a plan view and covering more than 70% of the central region in the plan view.

17. The image sensor of claim 16, wherein the common color filter is a red color filter or a green color filter.

18. The image sensor of claim 17, further comprising:
an isolation layer separating first to fourth pixel regions, and
wherein the isolation layer is in contact with the first surface and the second surface.

19. The image sensor of claim 18, wherein the first portion covers more than 85% of the central region in the plan view.

20. The image sensor of claim 16, further comprising:
a second layer on the first layer; and
a third layer on the second layer,
wherein the second layer comprises a plurality of transistors, and
wherein the third layer comprises a second substrate and a plurality of transistors.
